(19) United States
(12) Patent Application Publication
(10) Pub. No.: US 2019/0020272 A1
(43) Pub. Date: Jan. 17, 2019

(54) INTEGRATED DC-DC BOOST CONVERTER WITH GALLIUM NITRIDE POWER TRANSISTOR

(71) Applicant: GLOBALFOUNDRIES Singapore Pte. Ltd., Singapore (SG)

(72) Inventors: Donald DISNEY, Cupertino, CA (US); Fanyi MENG, Chengdu (CN); Xiang YI, Singapore (SG); Chirn Chye BOON, Singapore (SG)

(21) Appl. No.: 15/648,105

(22) Filed: Jul. 12, 2017

(51) Int. Cl. H02M 3/06; H01L 33/00

(52) U.S. Cl. CPC H02M 3/06; H02M 1/00; H01L 33/007

(57) ABSTRACT

Integrated circuits, wafer level integrated III-V power device and CMOS driver device packages, and methods for fabricating products with integrated III-V power devices and silicon-based driver devices are provided. In an embodiment, a boost converter circuit includes an inductor; a power switch having a conducting state and blocking state; and a control circuit for controlling the power switch from the conducting state to the blocking state for controlling flow of the current in the inductor, wherein the control circuit comprises a silicon integrated circuit comprising bipolar CMOS transistors, wherein when the power switch comprises a first GaN transistor, and wherein the power switch and silicon integrated circuit are electrically and mechanically coupled by way of flip chip bonding.

### TECHNICAL FIELD

The present disclosure relates to semiconductor processing. In particular, the present disclosure relates to group III-V power devices and their integration with driver devices, such as CMOS-based or silicon-based driver devices.

### BACKGROUND

Direct current-direct current (DC-DC) power conversion applications are used in consumer and industrial applications and communications. The boost converter is used to “step-up” an input voltage to some higher level, required by a load. This capability is achieved by storing energy in an inductor and releasing it to the load at a higher voltage. For low to medium power applications, fully integrated DC-DC boost converters are commonly used. Monolithically integrated silicon power transistors such as lateral double-diffused metal oxide semiconductor (LDMOS) transistors are typically used for the power switches, and are quite area efficient and capable of switching at relatively high frequencies (i.e. above 1 MHz) at low voltages (i.e. below 80V). However, silicon LDMOS efficiency and switching frequency decrease rapidly with increasing voltage rating. Thus, it is not practical to make boost converters with integrated LDMOS switches for high-voltage applications.

Group III-V semiconductor devices are semiconductor devices formed from compounds with at least one group III element (IUPAC group 13) and at least one group V element (IUPAC group 15). Group III elements include boron, aluminum, gallium, indium, and thallium. Group V elements include nitrogen, phosphorus, arsenic, antimony, and bismuth. Currently, nitrogen is the most commonly used group V element in semiconductor devices.

Group III-V semiconductor compounds, such as gallium nitride (GaN) and its related alloys, exhibit large bandgap and high electron saturation velocity compared to silicon, which makes them excellent candidates for applications in high voltage, high temperature and high-speed power electronics. To overcome the limitations of silicon LDMOS devices in high voltage boost converters, noted above, it is beneficial to make boost converters including silicon-based control circuitry (e.g. complimentary metal oxide semiconductor (CMOS) or Bipolar-CMOS-DMOS (BCD) circuitry) for the control functions and GaN power devices for the power switches. In prior-art approaches, the silicon CMOS or BCD circuits are typically formed on a first substrate, such as a silicon (100) substrate and GaN devices are formed on a second substrate, such as sapphire or silicon carbide (SiC) or a silicon (111) substrate. The GaN devices and silicon devices are then connected together by assembling the GaN and silicon devices in separate semiconductor packages and connecting them on a printed circuit board, or by assembling the GaN and silicon devices into a single package and connecting them via the package conductive materials and/or wire bonds.

To enjoy the advantages of GaN power switches for higher performance boost converters, the GaN switches must be interconnected with silicon-based control circuits, generally fabricated as integrated circuits (IC) using CMOS and/or BCD technologies. The most common approach to combining silicon ICs with GaN switches involves packaging the silicon IC in a first semiconductor package, packaging the GaN switch in a second semiconductor package, mounting both packages onto a printed circuit board (PCB), and interconnecting them using copper traces on the PCB. Another conventional approach involves placing the silicon IC and GaN switch in a single semiconductor package and interconnecting them using the package leadframe and/or bond wires. In both of these conventional approaches, the performance is limited by the parasitic inductance and resistance that it introduced by the interconnections between the silicon IC and GaN switches.

These prior art approaches realize high-voltage boost converters with much higher performance than integrated boost converters with silicon LDMOS transistors. However, their performance is limited by the parasitic inductance and resistance that it introduced by the interconnections between the separate silicon integrated circuit (IC) and GaN transistors. In addition, the overall area of the prior-art approaches is large due to the side-by-side arrangement of the GaN power devices and silicon IC. Moreover, the ability of the IC to sense and control the GaN power devices is limited due to their physical separation.

A need therefore exists for methodology for producing boost converters with integrated Group III-V power transistors and silicon-based ICs to enable higher efficiency, increased switching frequency, reduced parasitic inductance and resistance, smaller area, and enhanced control, and the related device.

### SUMMARY

The present disclosure provides a DC-DC boost converter that includes silicon-based driver circuitry and one or more Group III-V devices, such as GaN power transistors, mounted directly on top of the silicon die. By replacing a silicon power transistor with a GaN power transistor, a much lower on-resistance is obtained which increases the efficiency of the boost converter substantially. By way of example, for a 200V rated device, the on-resistance of a GaN power transistor may be about ¼ to 1/10 that of a silicon LDMOS transistor with the same area. The GaN power transistor allows much higher switching frequency, which reduces the size of external passive components, such as inductors and capacitors, for a much smaller total solution. A GaN power transistor also allows much higher output current, increasing the output power achievable in a given area by a factor of four or more, enabling a wider range of applications.

The direct stacking arrangement of the present disclosure also minimizes parasitic resistance, inductance, and capacitance which results in faster transient response, higher switching speeds, lower power loss reduced ringing for improved circuit stability, and other performance improvements. Moreover, the close coupling of the GaN power transistor and the driver circuitry allows for direct sensing of the GaN power transistor, including sensing of temperature, current and/or voltage. Reduced packaging costs are achieved compared to conventional processes that separately package a silicon driver and one or more GaN power transistor(s), and the total area is greatly reduced.

Another aspect of the present disclosure is driver circuitry that is fabricated by conventional silicon CMOS or BCD processing with bond pads designed to allow direct attachment of the Group III-V power transistors to the bond pads of the driver IC using chip-on-wafer assembly.

Yet another aspect includes a main boost switch that is a low-side GaN power device, preferably a GaN high electron mobility transistor (HEMT), mounted directly on top of the silicon die. The main boost switch can be a normally-OFF device or a normally-ON device connected in series with a normally-OFF silicon transistor.

Another aspect of the present disclosure is to provide a boost diode integrated directly on top of the silicon die. The boost diode can be a diode-connected GaN power transistor, a GaN/silicon carbide (SiC) diode, or a GaN transistor used as a synchronous rectifier. Heat dissipation of both the driver IC and the GaN power transistor(s) are handled by the IC driver substrate/package.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

Aspects of the present application include a boost converter circuit including: an inductor; a power switch having a conducting state and blocking state; and a control circuit for controlling the power switch from the conducting state to the blocking state for controlling flow of the current in the inductor, wherein the control circuit includes a silicon integrated circuit including bipolar CMOS transistors, wherein when the power switch includes a first GaN transistor, and wherein the power switch and silicon integrated circuit are electrically and mechanically coupled by way of flip chip bonding.

Aspects include the silicon integrated circuit being configured to provide for dissipation of heat generated in the power switch. Additional aspects include the control circuit having a gate drive circuit, the first GaN transistor including a gate electrode, and the gate drive circuit is electrically coupled to the gate electrode by a conductive material. Other aspects include a boost diode, wherein the boost diode is a silicon PN junction diode, or a merged-PN-Schottky (MPS) diode formed as part of the control circuit. Yet other aspects include a boost diode, wherein the boost diode is a diode-connected GaN transistor, the diode-connected GaN transistor being electrically and mechanically coupled to the silicon integrated circuit by way of flip chip bonding. Another aspect includes a synchronous rectifier, wherein the synchronous rectifier is a second GaN transistor, the second GaN transistor being electrically and mechanically coupled to the silicon integrated circuit by way of flip chip bonding, the control circuit being configured to control the second GaN transistor. Still other aspects include a parasitic inductance between the gate drive circuit and the gate electrode, the parasitic inductance having a value less than 0.1 nH. Other aspects include the power switch and silicon integrated circuit being electrically and mechanically coupled by way of flip chip bonding. Further aspects include the control circuit being configured for direct sensing of at least one property of the power switch, the at least one property including temperature, current, or voltage.

Another aspect of the present application includes a boost converter controller including a power switch having a first GaN transistor fabricated on a first silicon substrate; a control circuit including an integrated circuit fabricated on a second silicon substrate and configured for controlling the power switch, wherein the power switch and integrated circuit are electrically and mechanically coupled by flip chip bonding using a conductive material.

Additional aspects include the control circuit including a current sense function to determine a magnitude of a current flowing through the power switch, and wherein a voltage drop across the GaN transistor provides an input for the current sense function. Other aspects include the current sense function having a provision to be trimmed to reduce a variation in the current sense output corresponding to a variation in one or more characteristics of the GaN transistor.

Yet another aspect of the present disclosure includes a method including forming a GaN power switch having a conducting state and blocking state; forming a boost converter control circuit on a silicon substrate, the control circuit configured to control the power switch from the conducting state to the blocking state for controlling flow of the current; and electrically and mechanically coupling the power switch and control circuit.

Further aspects include electrically and mechanically coupling the power switch on top of the control circuit by flip chip bonding. Other aspects include transferring the electrically and mechanically coupled power switch and control circuit to a semiconductor package. Other aspects include a parasitic inductance between the control circuit and the power switch having a value less than 0.1 nH. Further aspects include electrically and mechanically coupling a plurality of power switches on top of the control circuit by flip chip bonding. Yet another aspect includes by way of the control circuit, controlling a percentage of time the power switch is in the conducting state, the percentage of time capable of exceeding 95%. Further aspects include configuring the control circuit to directly sense a temperature, a current, and/or a voltage of the power switch.

Yet another aspect of the present disclosure includes a method including: forming an input source for receiving current; forming an output capacitor; forming an inductor; forming a boost diode or synchronous rectifier; forming a GaN power switch having a conducting state and blocking state; and forming a silicon based control circuit for controlling the GaN power switch from the conducting state to the blocking state for controlling flow of the current, wherein the current flows from the input source through the inductor and the GaN power switch when the GaN power switch is in the conducting state, and the current flows through the boost diode or synchronous rectifier and output capacitor when the GaN power switch is in the blocking state; and electrically and mechanically coupling the GaN power switch and silicon-based control circuit by flipchip bonding.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1A is a simplified schematic circuit diagram of a boost converter with a boost diode, according to an exemplary embodiment;

FIG. 1B is a simplified schematic circuit diagram of a boost converter with a synchronous rectifier in place of the boost diode, according to an exemplary embodiment;

FIG. 1C is a simplified schematic circuit diagram of a boost converter showing the parasitic inductances, according to an exemplary embodiment;

FIG. 2 is a process flow chart illustrating the steps to form an integrated GaN power device and CMOS driver device; and

FIG. 3 is a cross-sectional view illustrating a process for connecting a GaN HEMT device to a CMOS driver device to form an integrated GaN HEMT device and CMOS driver device, according to an exemplary embodiment;

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of low efficiency and low switching frequency with high-voltage silicon-based boost converters. The present disclosure integrates Group III-V power transistors, such as GaN power transistors, with silicon-based drive circuitry to provide increased efficiency and switching frequency and to reduce the overall device size. The present disclosure is particularly beneficial for high-voltage boost converters and high conversion ratios (output voltage divided by input voltage).

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

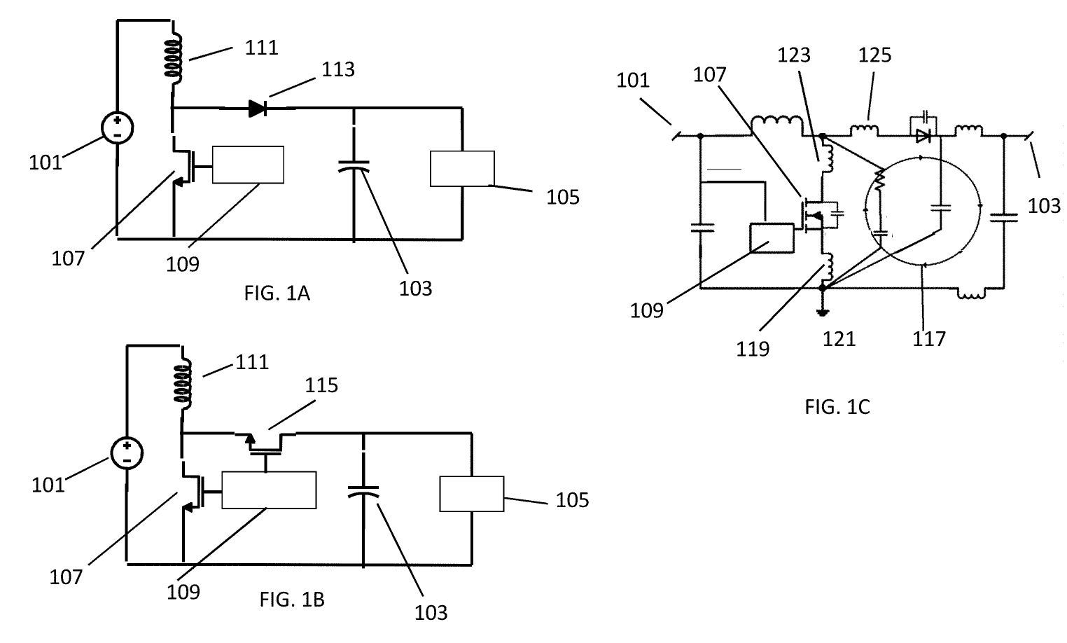

FIG. 1A is a simplified circuit schematic of a boost converter 100. The function of boost converter is to convert an input voltage (V_{IN}) 101 to an output voltage (V_{OUT}) with the purpose of transferring power from an input source 101 to a load 105. To accomplish this, power switch 107 is switched ON and OFF by a control circuit 109 to modulate the current flow in the boost converter. The power switch 107 can be a GaN power switch. When power switch 107 is ON (i.e. in a conducting state), current flows from input source 101 through inductor 111 and power switch 107. When power switch 107 is turned OFF (i.e. in a blocking state), the current flowing through inductor 111 now flows through boost diode 113 to output capacitor 103 and load 105. By modulating the percentage of time that power switch 107 is ON (i.e. the duty ratio, or on-time divided by the total period), control circuit 109 controls the conversion ratio (V_{OUT}/V_{IN}) as follows:

$$\frac{{V}_{o}}{{V}_{i}} = \frac{1}{1 - D}$$

The maximum conversion ratio is thus limited by the maximum duty ratio D, and to achieve very high conversion ratios requires very high duty ratios. Duty ratio D is limited by several factors including the on-resistance of power switch 107, the equivalent on-resistance of boost diode 113, and the switching transient time (time required to change from ON to OFF state and from OFF state to ON state) of power switch 107. For silicon LDMOS power switches, the specific on-resistance (on-resistance times area) R_{SP} increases rapidly with increasing voltage rating, making it difficult to cost-effectively realize on-resistances that are low enough to achieve high voltage boost converters with high conversion ratios. By comparison, GaN power devices rated for operation in the range of 80 to 200 Volts (V) provide R_{SP} values that are only about 10-20% of silicon LDMOS switches. Thus, GaN power switches consume much less area and provide much lower on-resistance, allowing the realization of high-voltage boost converters with larger duty ratios and therefore higher conversion ratios.

In addition to their far superior R_{SP} for a given voltage rating, high-voltage GaN switches also have much lower values of input capacitance, output capacitance, and gate charge compared to LDMOS switches, so they exhibit much faster switching transient times. For example, 100V GaN switches may exhibit switching times of less than 1 nanosecond (ns) compared to 5-20 ns for silicon LDMOS switches. As duty ratio increases, the ON-time consumes a larger fraction of the total available period, and the switching transient times can become a significant portion of the remaining OFF-time. Reducing switching transient times leaves more of the period available for further increases to the duty ratio. Higher switching frequencies reduce the total period, so reduced switching transient times are also important to enable boost converters to operate at higher frequencies.

In the present invention, GaN power switches are stacked directly on top of the silicon IC and interconnected using solder bumps or other suitable techniques. Thus, the parasitic inductance and resistance values are reduced dramatically. By way of example, the inductance of the wire bonds and leads in a conventional SO8 or DFN package may be in the range of 1 to 2 nH, and the PCB trace inductance may be about 1 nH per mm of length, while the present invention achieves inductance values under 0.1 nH, an reduction of 90% or more.

FIG. 1B shows the schematic of a boost converter which is substantially the same as that of FIG. 1A except that the boost diode 113 of FIG. 1A is replaced by a synchronous rectifier 115 in FIG. 1B. The synchronous rectifier 115 offers lower conduction loss compared to the boost diode 113, because the boost diode 113 has a forward knee voltage, and its conduction power loss is I×V_{F}, whereas the synchronous rectifier 115 is a switch with a conduction power loss of I²×R_{ON}. The synchronous rectifier 115 may include a silicon LDMOS devices, one of the standard elements offered in the IC process, thus obviating the need to integrate a second GaN power switch 107 on top of the IC. In other embodiments, the synchronous rectifier 115 may be a second GaN power switch (similar to 107).

As noted previously, a very high duty ratio D is required to achieve a high conversion ratio. For example, a boost converter with 5V input and 80V output requires a duty ratio of 94%. In this example, the power switch 107 is ON 94% of the total period T. Thus, the conduction loss of the power switch is a primary contributor to the overall power loss (P_{LOSS}=I²×R_{ON}×D/T). The GaN power switch 107 has large advantage compared to silicon LDMOS. The boost diode 113 conducts current for a very small percentage of the period (less than 6% after subtracting the switching transient times). Thus, the conduction loss of the boost diode 113 is a relatively small part of the overall power loss. This means that it is often not necessary to use a synchronous rectifier 115, or even a GaN or SiC diode. In another embodiment, a silicon P-N diode may be used. In yet another embodiment, a Schottky diode may be used, formed from elements of the IC process such as the silicide layer (e.g. Cobalt or Titanium or Nickel). In yet another embodiment, a merged-PN-Schottky (MPS) diode is used, formed from elements of the IC process. The ability to use a silicon IC based diode simplifies the fabrication of the present invention, as only a single GaN transistor needs to be integrated with the silicon IC.

FIG. 1C shows a boost converter schematic highlighting the parasitic components (i.e. unwanted circuit components are not shown for illustrative convenience, but rather are introduced due to the manner in which the main circuit components are interconnected). L_{PAR1} 119 is parasitic inductance produced by the interconnection from the source of the power switch to the ground pin 121 of the semiconductor package. Both the drain-source current and the gate charging current flow through L_{PAR1} 119. Any change in the drain source current will induce an opposing voltage across L_{PAR1} 119. This voltage will actively modify the gate source voltage of the power MOSFET. The effect will be more significant during turn-on and turn-off when I_{DS} and V_{GS} are changing quickly. By reducing the value of V_{GS} seen by the field effect transistor (FET), the common source inductance acts to increase the turn-on and turn-off times. The result is increased switching loss. Thus, reducing L_{PAR1} 119 is critical for improving the performance of the boost converter. The present invention reduces L_{PAR1} 119 by a factor of 10× or more, providing substantially faster switching and lower switching losses.

FIG. 1C also shows the critical loop 117 formed by power switch 107, boost diode 113, and output capacitor 103. Critical loop 117 carries fast transient currents that can cause large transient voltages as the current is switched ON and OFF. These unwanted transient voltages cause unwanted stress on the circuit components, which may cause reliability problems, and can also disrupt the proper operation of the boost converter. The present invention provides close coupling of GaN power switch 107 and boost diode 113, thus reducing the values of L_{PAR1} 119, L_{PAR2} 123, and L_{PAR3} 125 by at least 90%, which reduces the voltage transients to provide more reliable and more efficient operation.

In addition to reducing parasitic components, the present invention also greatly reduces the area of a high-voltage boost converter, compared to prior-art solutions. For example, a prior-art solution may include an IC package measuring 2×3 mm and a packaged GaN switch measuring 2×2 mm, mounted together on a PCB with required spacing of 1 mm, resulting in an overall PCB area of 6×2=12 mm². In the present disclosure, for example, the GaN switch is stacked directly on top of the IC, which can fit in the same 2×3 mm package and consume on 6 mm² of PCB area, a 50% reduction in area.

By providing close physical and electrical coupling of the silicon IC and GaN switch, the present invention also greatly enhances the ability of the IC to sense and control the GaN switch. For example, in prior-art solutions, the current flowing through the GaN switch is usually monitored by placing a discrete sense resistor between the source terminal of the GaN switch and ground, and feeding the voltage across this resistor to the control IC. In the present disclosure, a sense resistor may be fabricated on silicon IC itself, thus providing much closer coupling that is less prone to noise and voltage offsets, for greatly improved current sensing. To minimize the sense resistor value, which reduces power loss in the resistor, the integrated sense resistor may be formed from low-resistivity IC materials such as interconnect metallization layers and/or doped polysilicon layers. In certain embodiments, the sense resistor may be fabricated from a doped polysilicon layer that is relatively insensitive to changes in temperature, thus providing more accurate current sensing over a wide range of operating temperatures.

Close coupling of the GaN switch also allows the silicon IC to directly, accurately, and rapidly sense the actual voltages on the drain, gate, and source terminals of the GaN switch. In prior-art solutions, the higher parasitic resistance and inductances reduce the accuracy and speed with which the IC can sense the GaN terminal voltages. By improving the sensing ability, the present disclosure provides faster and more precise control of the GaN power switch for improved efficiency and reliability, and shorter dead-times for synchronous rectifier operation, for higher efficiency.

In certain embodiments, the GaN switch is mounted on top of the IC while the silicon is still in wafer form, before it has been diced into individual ICs. In other words, the GaN power switch and control circuit can be tested together at the wafer level, and the control circuit can be trimmed (i.e. adjusted) to account for variations in the GaN transistor performance. In prior-art solutions, the control IC is packaged separately from the GaN transistor, and they are only tested together after being assembled onto the PCB. In this case, it is not possible to trim each IC to match the GaN switch that it is paired with, so the design must provide much more tolerance to accommodate the full range of possible IC and GaN switch variations. In the present disclosure, each IC can be trimmed to match its paired GaN switch characteristics, allowing much less over-design, which improves performance and reduces variability in the final boost converter product. For example, during wafer-level testing of the GaN switch and IC combination, the gate drive circuit can be trimmed to match the threshold voltage and input capacitance of that specific GaN switch, such that the resulting switching behavior is consistent from on IC/GaN pair to the next.

In another example, the on-resistance of the GaN switch can be used to allow the IC to monitor the current flowing through the GaN switch, obviating the need for a sense resistor in series with the source terminal of the GaN switch. This is not be possible in prior-art solutions, because the variation in on-resistance from one GaN switch to the next may be as high as +/−20%, which when added to the independent variations on the IC circuitry, would result in a variation in the current sensing function that is too large to be useful. In the present disclosure, analog circuit trimming techniques and combined GaN/IC wafer-level testing allow the current sense function to achieve high accuracy and repeatability (e.g. +/−5% or better).

Connecting the source of the GaN switch directly to ground has an additional advantage in thermal performance. The substrate of the IC is also at ground potential. If the GaN source is also grounded, then the IC metallization layers and vias can be used to create a thermal path with very low thermal resistance, thus allowing extraction of heat from the GaN switch through these thermal vias down to the substrate. In this manner, significant heat can be removed from the GaN switch.

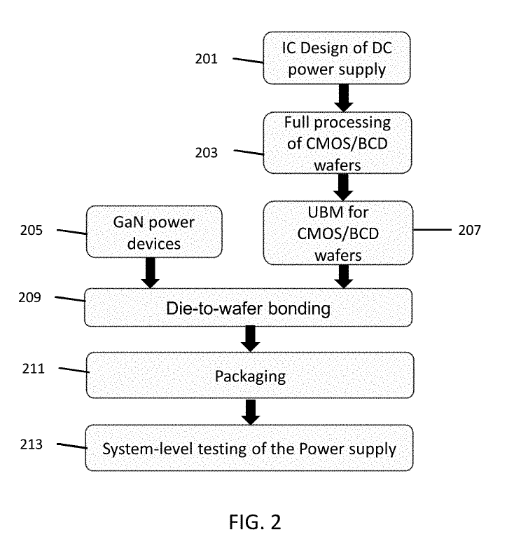

Adverting to FIG. 2, a process flow chart detailing the steps to form an integrated GaN HEMT device and CMOS driver device is shown. In step 201, the IC layout design of the DC power supply is performed with modeling software. In step 203, the CMOS or bipolar-CMOS-DMOS (BCD) wafers are fully processed to form the individual IC components over a substrate. In this particular example, the power integrated circuit includes a DC/DC voltage conversion integrated circuits including buck converters, boost converters, drivers, motor drivers, etc. The power integrated circuit includes CMOS or BCD transistors configured to form a gate driver circuit. The GaN power transistor is separately processed in step 205. Under-bump metallization (UBM) for the CMOS or BCD wafers are formed in step 207. Next, in step 209, a die-to-wafer transfer assembles the CMOS/BCD wafers with the GaN HEMT by way of the flip chip bonding connection to form an integrated unit(s). In step 211, the integrated unit or units are transferred to a package utilizing conventional semiconductor packaging and assembly equipment and techniques. Heat dissipation of both the driver IC and the GaN power transistor(s) are handled by the IC driver substrate/package. In step 213, system-level testing of the now formed power supply can be conducted.

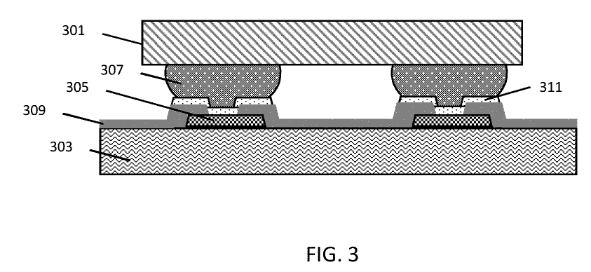

In FIG. 3, an example of an integrated GaN power transistor 301 and CMOS circuit 303, produced by the process of FIG. 2 is illustrated. This example of a DC-DC boost converter integrated circuit includes silicon-based driver circuitry produced by conventional CMOS or BCD processing with bond pads designed to allow direct attachment of the GaN power transistors. The one or more GaN power transistors 301 are attached to the CMOS circuit 303 by way of the bond pads 305 using chip-on-wafer assembly. In FIG. 3, the main boost switch is a low-side GaN power transistor 301, such as a GaN HEMT, mounted directly on top of the CMOS circuit 301. A boost diode (e.g. 113 in FIG. 1A) can be integrated directly on top of the CMOS circuit 301 and can be selected from a diode-connected GaN transistor, a GaN/SiC diode or a GaN transistor used as a synchronous rectifier (e.g. 115 in FIG. 1B). In FIG. 3, a die attach region 307 may include a solder bump or solder layer, conductive epoxy or another suitable conductive and malleable material that may harden and adhere to provide a mechanical and electrical connection between GaN power transistor 301 and the gate driver circuit region of the CMOS circuit 303. As shown, a portion of the passivation layer 309 is removed from the bond pads 305 to provide exposed surfaces of the bond pads 305. An UBM layer 311 is formed over the bond pads 305 and in contact with the exposed surfaces of the bond pads 305.

The embodiments of the present disclosure can achieve several technical effects, including higher efficiency, faster switching and smaller footprint. The present disclosure enjoys industrial applicability in any of various industrial applications, e.g., microprocessors, smart phones, mobile phones, cellular handsets, set-top boxes, DVD recorders and players, automotive navigation, printers and peripherals, networking and telecom equipment, gaming systems, digital cameras, and power conversion applications. The present disclosure therefore enjoys industrial applicability in any of various types integrated boost converters.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

1. A boost converter circuit comprising:
an inductor;
a power switch having a conducting state and blocking state; and
a control circuit for controlling the power switch from the conducting state to the blocking state for controlling flow of the current in the inductor,
wherein the control circuit comprises a silicon integrated circuit comprising bipolar complementary metal-oxide-semiconductor (CMOS) transistors,
wherein the power switch comprises a first GaN transistor,
wherein the power switch and silicon integrated circuit are electrically and mechanically coupled by way of flip chip bonding, and
wherein the silicon integrated circuit is configured to provide for dissipation of heat generated in the power switch.

2. (canceled)

3. The boost converter according to claim 1, wherein the control circuit comprises a gate drive circuit, the first GaN transistor comprises a gate electrode, and the gate drive circuit is electrically coupled to the gate electrode by a conductive material.

4. The boost converter according to claim 1, further comprising:
a boost diode,
wherein the boost diode is a silicon PN junction diode, or a merged-PN-Schottky (MPS) diode formed as part of the control circuit.

5. The boost converter according to claim 1 further comprising:
a boost diode,
wherein the boost diode is a diode-connected GaN transistor, the diode-connected GaN transistor being electrically and mechanically coupled to the silicon integrated circuit by way of flip chip bonding.

6. The boost converter according to claim 1 further comprising:
a synchronous rectifier,
wherein the synchronous rectifier is a second GaN transistor, the second GaN transistor being electrically and mechanically coupled to the silicon integrated circuit by way of flip chip bonding, the control circuit being configured to control the second GaN transistor.

7. The boost converter according to claim 3, further comprising:
a parasitic inductance between the gate drive circuit and the gate electrode, the parasitic inductance having a value less than 0.1 nH.

8. (canceled)

9. The boost converter according to claim 1,
wherein the control circuit is configured for direct sensing of at least one property of the power switch, the at least one property comprising temperature, current, or voltage.

10. A boost converter controller comprising:
a power switch comprising a first GaN transistor fabricated on a first silicon substrate;
a control circuit comprising an integrated circuit fabricated on a second silicon substrate and configured for controlling the power switch,
wherein the power switch and integrated circuit are electrically and mechanically coupled by flip chip bonding using a conductive material.

11. The boost converter controller according to claim 10,
wherein the control circuit comprises a current sense function to determine a magnitude of a current flowing through the power switch, and
wherein a voltage drop across the GaN transistor provides an input for the current sense function.

12. The device according to claim 11, wherein the current sense function has a provision to be trimmed to reduce a variation in the current sense output corresponding to a variation in one or more characteristics of the GaN transistor.

13. A method comprising:
forming a GaN power switch having a conducting state and blocking state;
forming a boost converter control circuit on a silicon substrate, the control circuit configured to control the power switch from the conducting state to the blocking state for controlling flow of the current; and
electrically and mechanically coupling the power switch and control circuit by flip chip bonding.

14. (canceled)

15. The method according to claim 13, further comprising:
transferring the electrically and mechanically coupled power switch and control circuit to a semiconductor package.

16. (canceled)

17. The method according to claim 13, further comprising:
electrically and mechanically coupling a plurality of power switches on top of the control circuit by flip chip bonding.

18. The method according to claim 13, comprising:
by way of the control circuit, controlling a percentage of time the power switch is in the conducting state.

19. The method according to claim 13, further comprising:
configuring the control circuit to directly sense a temperature, a current, and/or a voltage of the power switch.

20. A method comprising:
forming an input source for receiving current;
forming an output capacitor;
forming an inductor;
forming a boost diode or synchronous rectifier;
forming a GaN power switch having a conducting state and blocking state; and
forming a silicon based control circuit for controlling the GaN power switch from the conducting state to the blocking state for controlling flow of the current,
wherein the silicon based control circuit is configured to provide for dissipation of heat generated in the GaN power switch,
wherein the current flows from the input source through the inductor and the GaN power switch when the GaN power switch is in the conducting state, and
the current flows through the boost diode or synchronous rectifier and output capacitor when the GaN power switch is in the blocking state; and
electrically and mechanically coupling the GaN power switch and silicon-based control circuit by flipchip bonding.
